(19) United States
(12) Patent Application Publication
(10) Pub. No.: US 2025/0347718 A1
(43) Pub. Date: Nov. 13, 2025

(54) Ultra-fast Current Probe

(71) Applicant: Cambridge Enterprise, Ltd., Cambridge (GB)

(72) Inventors: Luke Shillaber, Cambridge (GB); Teng Long, Cambridge (GB)

(73) Assignee: Cambridge Enterprise, Ltd., Cambridge, GB (GB)

(21) Appl. No.: 18/868,747

(22) PCT Filed: May 23, 2023
(86) PCT No.: PCT/EP2023/063841

§ 371 Date: Nov. 23, 2024

(30) Foreign Application Priority Data
May 23, 2022 (GB) 2207509.7

(51) Int. Cl. G01R 1/20; G01R 1/30

(52) U.S. Cl. CPC G01R 1/203; G01R 1/30

(57) ABSTRACT

A radio/microwave frequency current probe comprising one or more resistive elements electrically connected between a current input region and a current output region, and a stack of layers each comprising a dielectric material. For each of the resistive elements, the current probe further comprises a plurality of conductive paths each separated by one or more of the layers. A first set of the conductive paths are configured to provide a current path between the current input region and the resistive element, while a second set of conductive paths are configured to provide a current path between the resistive element and the current output region. The plurality of conductive paths are arranged such that the first and second sets of conductive paths alternate in the stack of layers. The current probe may also be integrated into current measurement systems.

### TECHNICAL FIELD OF THE DISCLOSURE

The present disclosure relates to an ultra-fast current probe suitable for use in current measurement systems, as well as current probes and measuring systems comprising said ultra-fast current probe.

### BACKGROUND OF THE DISCLOSURE

The present disclosure generally provides current probes, and in particular to ultra-fast current probes suitable for use in systems measuring currents with high switching speeds, such as probes with bandwidths in the microwave and/or radio (RF) frequencies.

Many current measurement systems are commercially available, each offering differing advantages and drawbacks, while further systems have been proposed to attempt to address some of the disadvantages of existing commercially available solutions.

For example, many existing systems utilise Rogowski coils, which can perform magnetic measurement methods utilising the principle of magnetic induction. These systems generally provide measurement circuits allowing for simultaneous measurements on both the high and low sides of a power loop. However, due to their reliance on induction, Rogowski coil based systems are unable to measure DC currents, and thus require a separate low bandwidth measurement system to monitor DC parameters such as transistor on-state loss. Furthermore, Rogowski coils require an output integrator to convert the induced voltage in the coil into a current measurement. The high frequency performance of the Rogowski coil is therefore typically limited by the performance of the integrator and the turn-to-turn capacitance of the coil itself, amongst other factors.

Other existing systems utilise coaxial current shunts to measure the voltage drop across a resistor of known value. Such systems generally provide a band-pass bandwidth in the GHz range and offer reasonable measurement shielding due to the enclosed construction resulting in a low mutual inductance between the power and measurement loops. However, these systems typically have large insertion inductances, which has the potential to generate large enough voltages to damage semiconductor devices and may also promote power loop ringing. Furthermore, a proportion of this inductance often appears between the measurement terminals of the device, thereby introducing an inductive zero into the frequency response transfer function. This inductive zero (also called a parasitic zero) results in a scaled derivative of the real current being present in the output signal, and may reduce the accuracy of the measurements if the frequency of the parasitic zero falls within the frequencies of interest (i.e. the frequencies being measured in a particular test).

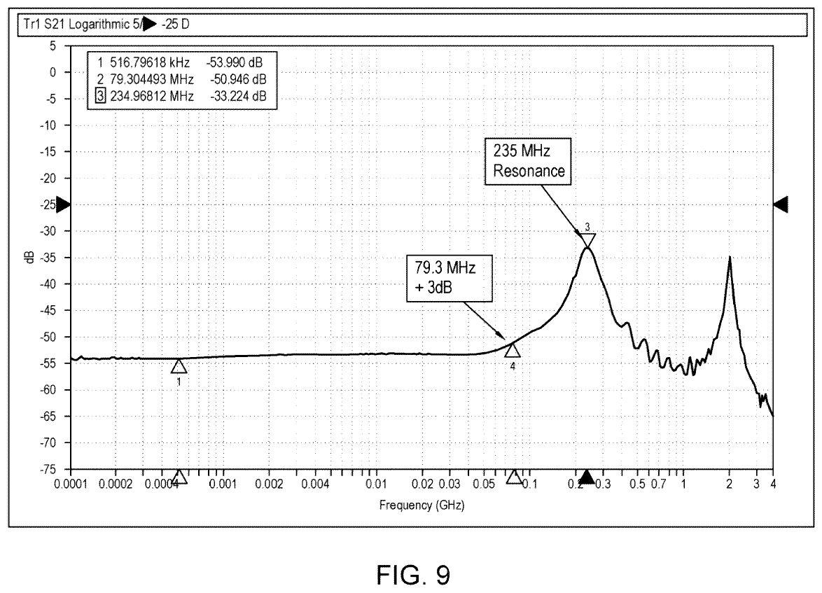

Thus, existing current measurement systems for wide-bandgap device testing have significant limiting factors for wide-bandgap device measurement. These factors include, for example, bandwidth, signal distortion, insertion inductance and device footprint. The issues presented by these limiting factors are becoming increasingly prevalent as switching edges tend towards sub 10 ns times, with no commercially available current probes being suitable for such a purpose. For example, FIG. 9 shows a frequency response of a known coaxial current probe with an insertion inductance of approximately 6.5 nH. The differentiator type response limits the “flat” ±3 dB probe bandwidth to only 79.3 MHz, with resonant peaks at 235 MHz and 2 GHz that are caused by the large inductance of the system. This large inductance may resonate with the capacitance of the circuit or device being tested, further distorting and reducing the accuracy of the measurement results. To extend the “flat” portion of the bandwidth, high bandwidth current probes often require a large resistance in the tens or hundreds of milliohms.

Switching times with nanosecond and sub-nanosecond intervals provide several benefits, such as reduced switching losses, increased switching frequencies and smaller passive component sizes. However, these fast switching times require high rates of change of current, making the power devices susceptible to over-voltage damage from parasitic inductance in the power loop. This presents challenges in measuring the device switching current accurately and in turn makes accurate measurements of device switching energy and stored charge difficult.

Traditional current measurement systems and methods as described above therefore do not have the required frequency response to view the switching edge accurately at high frequencies and/or have a high parasitic inductance that can significantly alter switching performance and cause damage to the power device.

The Applicant has therefore recognised a need for current measurement systems and components suitable for high switching frequencies.

### SUMMARY

In general, aspects of the present disclosure may provide measuring systems addressing the issues described above. Broadly, aspects of the present disclosure provide an ultra-fast current probe that utilises mutual inductance cancellation to reduce its inductance and/or increase its bandwidth into the radio (e.g. MHz) and/or microwave (e.g. GHz) frequencies or higher, and thereby facilitate its use in performing accurate measurements on currents with higher switching rates (e.g. in excess of 10 or 100 A/nS) and/or shorter switching transients (e.g. nanosecond or sub-nanosecond switching periods).

According to a first aspect of the present disclosure, there is provided a radio/microwave frequency current probe comprising a stack of layers, wherein each layer comprises a dielectric material, and one or more resistive elements electrically connected between a current input region and a current output region. For each of the one or more resistive elements, the current probe comprises a plurality of conductive paths each separated by one or more of the layers, wherein a first set of conductive paths are configured to provide a current path between the current input region and the resistive element, and a second set of conductive paths are configured to provide a current path between the resistive element and the current output region. The plurality of conductive paths are arranged or interleaved such that the first and second sets of conductive paths alternate in the stack of layers.

Generally speaking, the mutual inductance cancellation between the input and output currents of the current probe facilitates a reduction in the total inductance of the current loop. Additionally, the stack of dielectric layers improves the mechanical strength of the probe, reducing the risk of failure due to mechanical stresses.

An ideal current probe may generally facilitate the formation of a measurement system with a low inductance, a low capacitance and a high bandwidth. However, in general the capacitance and inductance of a circuit are not fully independent, and it is often not possible to produce a design that achieves both a low inductance and a low capacitance.

For a current measurement system, a current probe with a high capacitance is typically more tolerable than a current probe with a high inductance, as many devices that will be measured using the measuring system will themselves have a relatively high capacitance. As a result, the current probes described herein aim to provide a low inductance and high bandwidth, even at a cost of a potentially higher current probe capacitance.

The current probe is formed from a stack of layers, such as dielectric layers. A current input region and a current output region may be provided on opposing sides of the layer stack. For example, the current input region may be provided on a “top” surface of the stack, while the current output region may be provided on a “bottom” surface of the stack, such that the input and output regions are separated in the stacking direction. As used herein, the stacking direction or dimension refers to the direction of separation between the top and bottom layers of the stack of layers. By providing the input and output regions on opposing sides of the stack, the current probe may be conveniently inserted into and/or connected to an external system by e.g. a soldered connection or a clamped connection, such as a bus-bar connection, thereby enhancing the versatility of the device. The input and output regions may be aligned on the opposing surfaces of the stack, i.e. so that the input/output regions are only separated in the stacking direction, to further improve the ease of connecting the current probe to external systems.

In implementations, the interconnect region between the current probe and an or any external system may comprise a similar multilayer structure to that described in relation to the current probe, for example with multiple current paths being separated by dielectric layers. The multilayer structure at the interconnect region may facilitate mutual induction cancellation of the insertion inductances, thereby reducing a total system inductance.

The resistive element(s) may be mounted on a surface of the stack of layers, and, preferably, mounted on a surface of the stack such that it is spatially separated from the input and/or output regions. For example, the input current region and the resistive element or elements may both be mounted on a “top” surface of the stack of layers, and separated in the lateral and/or longitudinal directions perpendicular to the stacking direction. As such, current flowing between the resistive element(s) and the input/output regions respectively may flow in opposite directions to each other, and in both cases perpendicularly to the stacking direction. The resistive element may therefore comprise any suitable surface mounted device (SMD), such as a SMD resistor or resistive film that can be deposited on or attached directly to the stack of layers. In further implementations, the resistive elements can be combined with or replaced by one or more other suitable passive sensing elements. For example, the resistive element(s) may be replaced by a (PCB based) Rogowski coil or a current transformer.

Conductive paths are therefore provided for between the resistive element(s) and the input/output regions. The conductive paths may be provided on top and/or bottom surfaces or some or all of the layers of the stack of layers. The set of conductive paths that provide a current path between the input region and the resistive element may be collectively referred to as the input conductive or current paths, while the set of conductive paths that provide a current path between the output region and the resistive element may be collectively referred to as the output conductive or current paths. The set of input conductive paths and output conductive paths may each be connected by input and output path vias respectively.

The input and output current paths alternate within the stack of layers, such that the input and output current paths are interleaved in the stacking direction. For example, in a stack comprising a first layer, a third layer and a second layer between the first and third layers, a “top” surface of the stack (e.g. corresponding to a “top” surface of the first layer) may comprise a first input current path between the current input region and the resistive element. A first output current path may be provided between the first and second layers. A second input current path may be provided between the second and third layers, and may be connected to the first input current path by vias such that the first and second input paths form an input current loop between the current input region and the resistive element. A second output current path may be provided on a “bottom” surface of the third layer, and may similarly be connected to the first output current path by vias such that the first and second output paths form an output current loop between the resistive element and the current output region. Thus, the stack of layers comprises a series of interleaved input and output current paths, with the input and output current paths alternating in the stacking direction (i.e. such that a given layer of the stack of layers will have an input current path along one surface and an output current path along the opposing surface).

It will be understood that the above structure may be generalised to a current probe with a stack comprising any number of layers. However, in implementations, the stack has an odd number of layers, such that the current probe comprises the same number of input and output conductive paths.

As the input and output current paths are provided along the surfaces of the stacked layers, they will generally carry parallel currents that flow in opposite directions (i.e. between the (current) input region and the resistive element for the input current paths, and between the (current) output region and the resistive element for the output current paths). The opposite flow directions of the input and output currents results in a mutual inductance between the input and output current paths, thereby facilitating mutual inductance cancellation and a reduced total inductance across the whole of the current path or loop between the input and output regions. Advantageously, by providing input and output current loops each comprising multiple input and output current paths (as described in the example above), the total mutual inductance between the current input and output paths may be increased, facilitating further reductions in the total inductance of the current probe.

Each layer of the stack of layers may be formed from a dielectric material suitable for radio and/or microwave frequencies, for example FR-4, ceramic materials, polymers (such as polyimide), and/or any other suitable material. In implementations some or all layers may be formed from different materials. The materials forming the layers may be selected based on the material properties to achieve e.g. a desired environmental/temperature resistance, better material consistency, etc. In one example, the current probe may be formed on a multilayer PCB, such as a PCB formed from FR-4. Alternatively, the current probe may be formed on a single layer substrate (such as a single layer PCB) with additional dielectric layers deposited on the substrate. The reduced thickness of the multiple dielectric layers may result in a higher capacitance and greater mutual inductance cancellation between the input and output current paths, when compared to an equivalently thick e.g. single layer PCB that provides only a single input and output current path along the top and bottom surfaces of the PCB respectively.

Each layer of the stack of layers may have a thickness of less than about 200 μm, for example between about 50 μm and about 200 μm. The thickness of the layers may be as small as possible within the given mechanical and manufacturing constraints of a particular implementation of the probe. In some implementations, one or more layers may be provided with an increased thickness (for example, between about 200 μm and about 1000 μm) in order to facilitate a reduction in the thickness of the other layers of the stack, while retaining a suitable mechanical strength for the current probe as a whole. The one or more thicker layers may comprise a middle layer or a substrate layer, and may also be referred to as a core.

Thus, the stack of layers in the current probe advantageously provides a lower probe inductance while maintaining the mechanical strength of an equivalently thick single layer design. The multilayer structure of the current probes in the present disclosure is therefore particularly suitable for use in insertion current probes, both due to the otherwise generally higher inductance of this connection method (relative to e.g. embedded current probes), and the requirement for insertion current probes to be handled while being inserted into external systems (and therefore being subject to higher mechanical stresses) or when being connected to the rest of a measurement system (e.g. to an oscilloscope).

It will be understood that for a given number of layers, and generally speaking, using layers with greater thicknesses results in an improved mechanical strength of the current probe, while layers with a lesser thickness may improve the mutual inductance cancellation between the input and output currents along the interleaved conductive paths.

In implementations, the current probe may comprise multiple resistive elements. By providing a desired impedance using multiple resistive elements each with a higher impedance rather than a single, lower impedance element, the skin effect experienced by the current probe may be reduced, which may otherwise result in a noticeable increase in the resistance of the element at higher switching frequencies. The multiple resistive elements may be arranged in any way. In an implementation, the resistive elements may be provided in a semi-circular arrangement, for example by placing the resistive elements with equiangular spacing to form the curved edge of a semicircle. By suitably arranging the angle and separation of adjacent resistive elements in this way, the proximity effect may be reduced, thereby reducing the effect of higher switching frequencies on the total impedance of the current probe. Additionally or alternatively, the resistive elements may be placed to reduce or minimise the overall size of the current probe, to make the current probe more compact.

More generally, arranging the resistive elements in parallel may reduce the insertion inductance of the current probe, and extend the bandwidth of an unfiltered probe by placing the inductive or parasitic zero at a higher frequency, making this term less likely to interfere with voltage measurements in the frequencies of interest. It will be understood that any resistive type shunt will introduce a parasitic zero term into a voltage measurement, as discussed further below.

The use of multiple resistive elements connected in parallel may also increase the resonant frequency of the current probe, and thereby move the resonant frequency of the current probe away from any frequencies of interest. It will be understood that the resonant frequency of the current probe depends on multiple factors, including the inductance of the probe.

The resistive elements may be mounted to the stack of layers such that a conductive path provided by the elements is adjacent to the stack of layers. For example, it will be understood that some SMD resistors comprise protrusions (also referred to as “feet” or “legs”) connected perpendicularly or approximately perpendicularly to a flat conductive surface connected to a ceramic substrate (also referred to as a “face”). Such an SMD resistor may be mounted such that its face (rather than its legs) is adjacent to the stack of layers. By configuring the resistive element or elements in this way, the distance between the current paths through the resistive elements and the conductive paths may be reduced, and thus the mutual inductance cancellation between the resistive elements and conductive paths may be enhanced.

The current probe according to the present disclosure may be incorporated into a current measurement system. Thus, according to a second aspect there is provided a system for measuring currents, comprising a one or more current probes according to the present disclosure. The system may advantageously facilitate measurements of currents with high switching speeds with improved accuracy and reduced distortion (due to the high bandwidth of the current probe) and lower electrical loading (inductive, resistive and capacitive loading) of the device under test (due to the reduced inductance of the current probe). It will be understood that in some systems high inductive loading may be a particular concern, as it can cause voltage spikes that may damage the device under measurement/test. Similarly, many systems utilising resistive current shunts have a bandwidth that is heavily dependent on the resistor size due to their high inductance and lack of filter. A current probe as described facilitates a reduction in the resistive loading of the system al allowing the use of a smaller resistor, with minimal consequences to the bandwidth (e.g. due to the low inductance and/or the addition of the filter).

In implementations, the system may comprise a compensation filter arranged to receive an output signal from the one or more current probes, the compensation filter configured to reduce or remove an inductive or parasitic zero from the output of the one or more current probes. By providing a compensation filter to reduce or remove the inductive zero of the current probe, the accuracy of the measurements provided by the current probe at high switching frequencies can be increased, particularly if the parasitic zero of the current probe would otherwise fall within the frequencies of interest. In implementations, the filter may be a low pass filter such as an inductive low pass filter. The use of an inductive filter advantageously facilitates adjustments of the filter inductance and resistance for an intended purpose. Thus, for high bandwidth differential amplifiers, some of which require specific feedback resistances in order to achieve their maximum bandwidth, an inductive filter may be preferred to a capacitive feedback low pass filter, as in these filters only the capacitor size is variable.

In a further implementation, the filter may comprise one or more resistive elements connected to a reference voltage. By utilising multiple resistive elements connected in parallel, the total inductance and therefore the total reactance of the filter system may be reduced, due to a reduction in the parasitic inductive reactance of the resistive elements. Advantageously, a lower filter inductance may move any additional unwanted filter poles/zeros away from the frequencies of interest, and therefore reduce or prevent distortions of the frequency response within the measurement frequency range. In other implementations, the filter may be a passive filter, and passive components of the filter may comprise partly or wholly of the input impedance of the oscilloscope or other measuring device.

The provision of multiple resistive elements connected in parallel may also lower the total resistance of the filter system, compared to a system with a single resistive element. The multiple resistive elements may therefore each have a higher resistance than a comparable single resistive element, in order to maintain the same total resistance of the system and reduce the impact of the skin effect. It will be appreciated that the multiple resistive elements in the compensation filter may also be arranged to reduce the proximity effect, as described above with regard to the multiple resistive elements of the current probe.

The system may further comprise one or more differential amplifier stages, for amplifying a signal output from the compensation filter and providing common mode noise rejection. The output of the differential amplifier stages may be provided to an external system or component, such as an oscilloscope. As such, the output of the differential amplifier stages may be configured based on the requirements of the external system input. For example, the system may provide an output suitable for an input of an oscilloscope. In implementations, the system may be a passive system without any differential amplifier stages.

The current probe and or system of the present invention may be provided in the form of a single product or device. For example, the current probe and/or system may be formed by depositing or positioning components on a printed circuit board.

According to a third aspect, there is provided a method for reducing the inductance of a current probe. The method comprises providing a first set of conductive paths and a second set of conductive paths in a stack of layers, wherein each layer comprises a dielectric material, and arranging the first and second set of conductive paths such that they alternate or are interleaved within the stack of layers. The method further comprises providing an input current through the first set of conductive paths and an output current though the second set of conductive paths, such that an inductance of the current probe is reduced by mutual inductance cancelation between the first and second set of conductive paths.

According to a fourth aspect, there is provided a method of measuring currents with microwave/radio frequencies, the method comprising providing an input current to a current probe, reducing the inductance of the current probe according to the third aspect, receiving an output signal from the current probe, wherein the output signal is representative of a current through the current probe, and providing the output signal to a measurement system.

The output signal provides a representation of the current in the probe that can be interpreted and/or displayed by an external measurement device or system, such as an oscilloscope. The output signal may be an output voltage, and/or may be proportional to the current through the current probe (and therefore, generally, the input current).

It will be understood that the additional features and steps described in relation to the devices, systems and apparatus of the present disclosure may be incorporated into the method.

### BRIEF DESCRIPTION OF THE EMBODIMENTS

Some embodiments of the disclosure will now be described by way of example only and with reference to the accompanying drawings, in which:

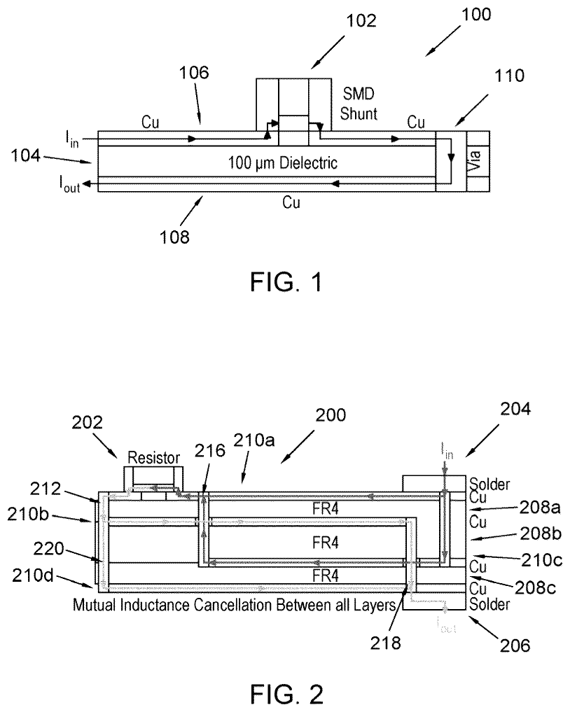

FIG. 1 schematically depicts a cross-sectional view of a current probe according to the present disclosure.

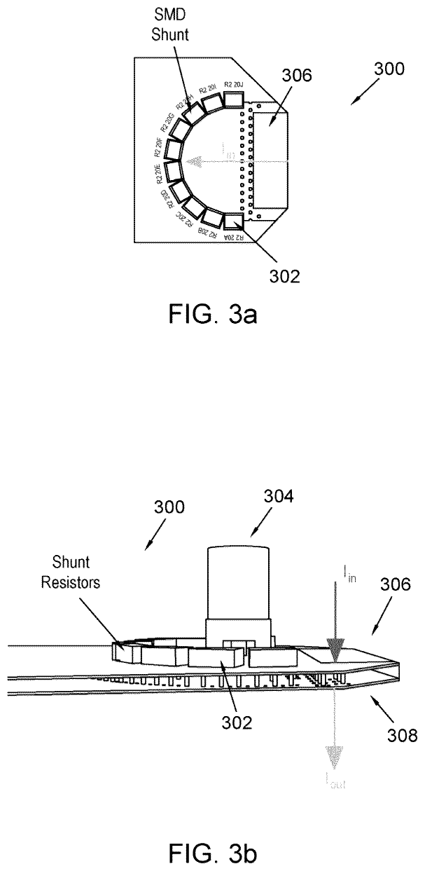

FIG. 2 schematically depicts a cross-sectional view of a current probe according to the present disclosure.

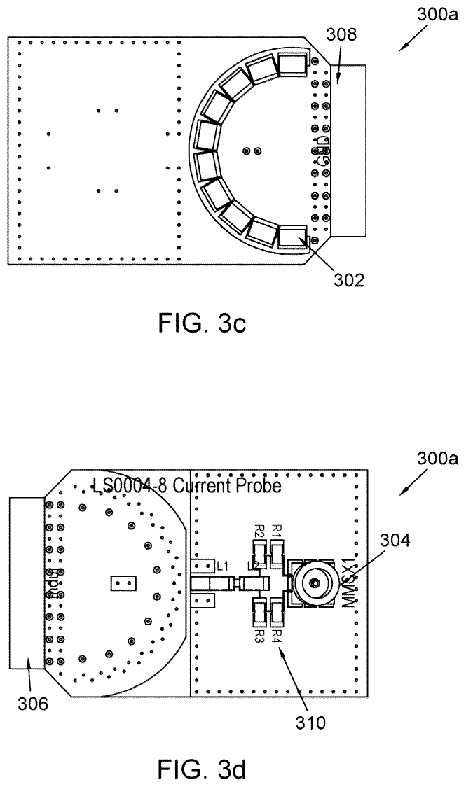

FIG. 3 schematically depicts top views (FIG. 3a, d), a bottom view (FIG. 3c) and a side view (FIG. 3b) of example current probes according to the present disclosure.

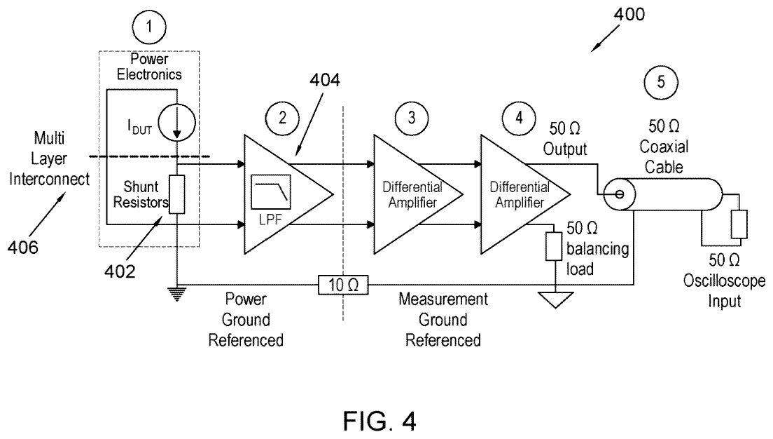

FIG. 4 depicts schematic diagrams of an example current measurement system according to the present disclosure.

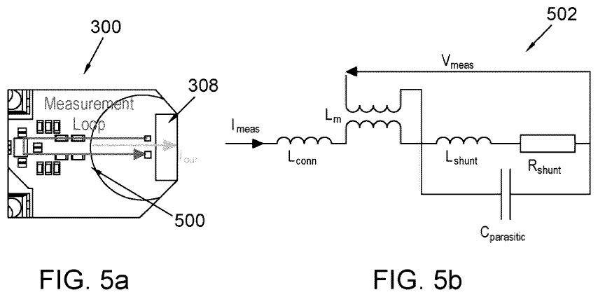

FIG. 5 schematically depicts a top view (FIG. 5a) and a circuit diagram (FIG. 5b) of an example current measurement loop for use with current probes according to the present disclosure.

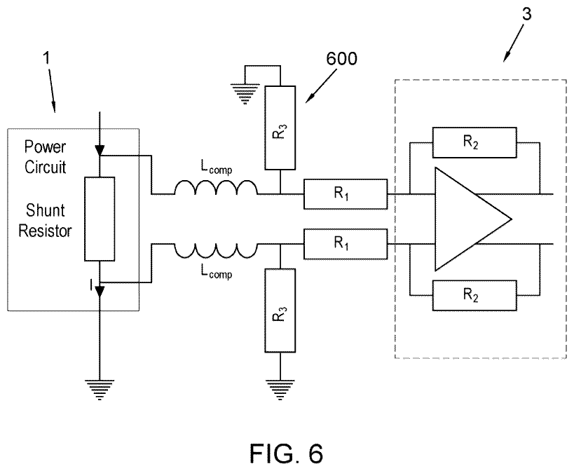

FIG. 6 depicts a circuit diagram of an example compensation filter according to the present disclosure.

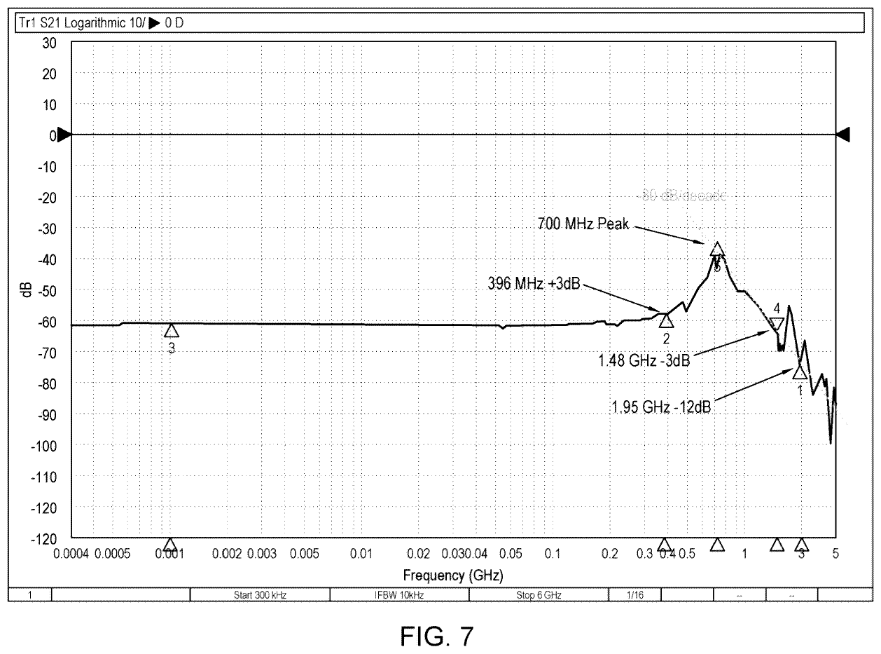

FIG. 7 shows a frequency response of a current probe according to the present disclosure.

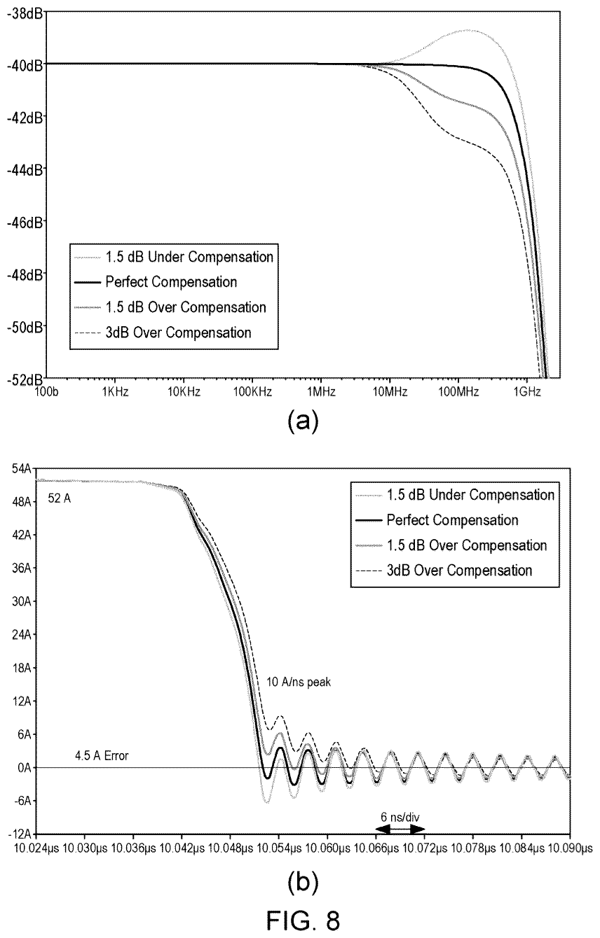

FIG. 8 shows simulated effects of compensation error in the time and frequency domains.

FIG. 9 shows a frequency response of an example known coaxial current probe.

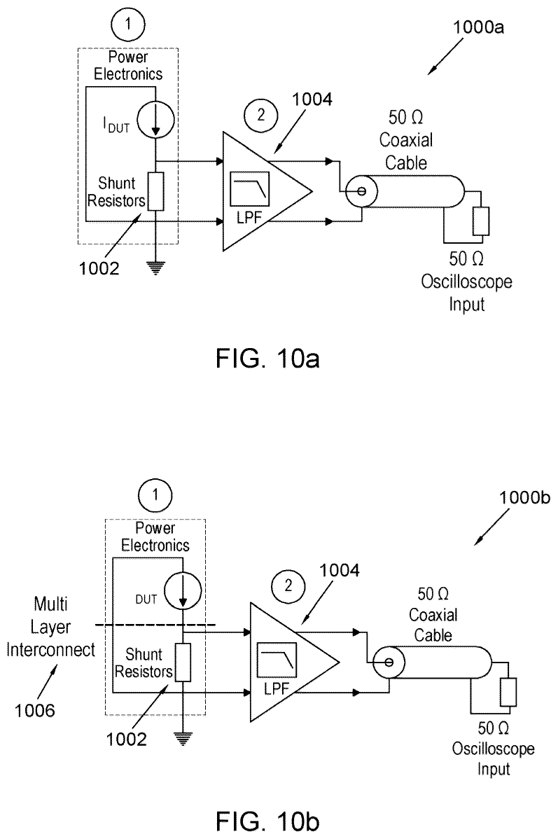

FIGS. 10A, B and C depict schematic diagrams of further example current measurement systems according to the present disclosure.

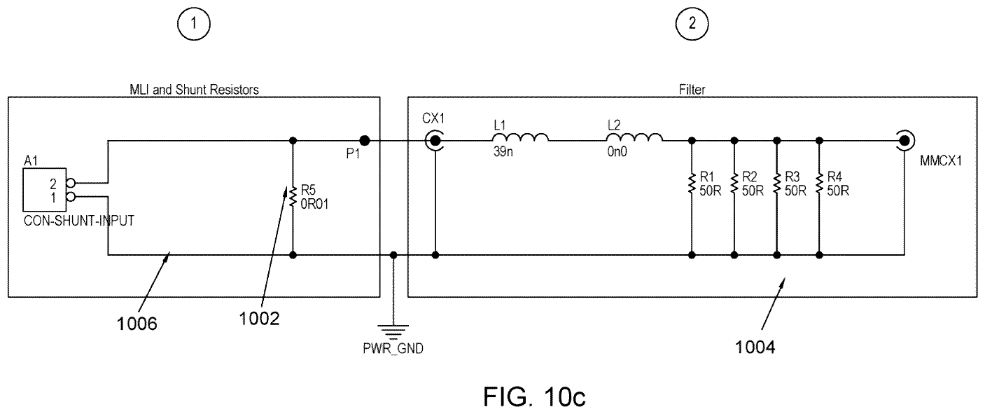

FIG. 11 schematically depicts a cross-sectional view of a current probe according to the present disclosure.

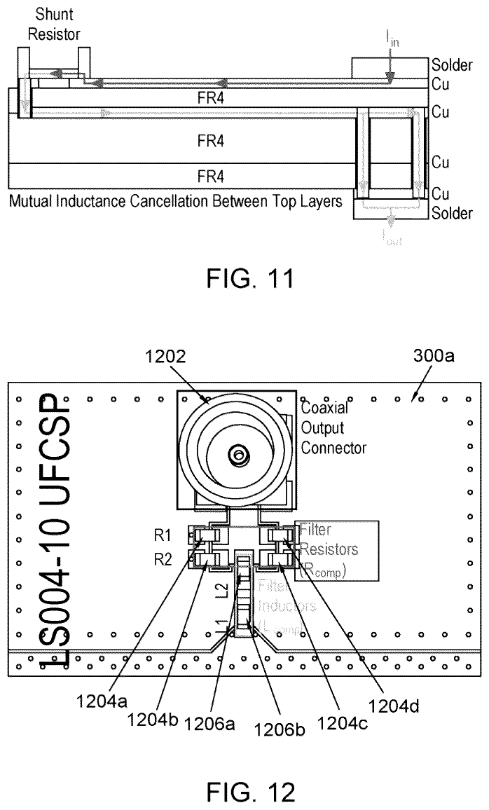

FIG. 12 schematically depicts a top view of an example current probe according to the present disclosure.

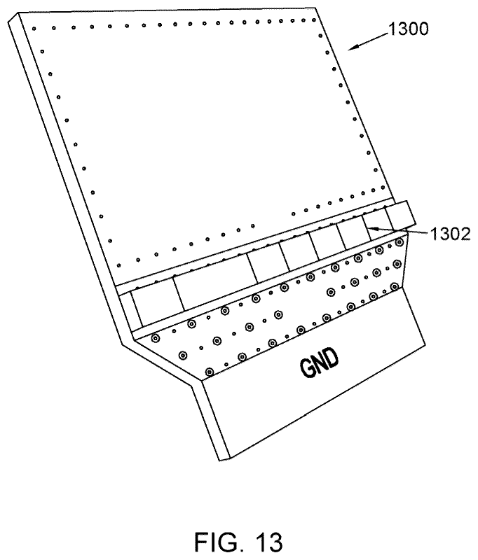

FIG. 13 schematically depicts a further perspective view of an example current probe according to the present disclosure.

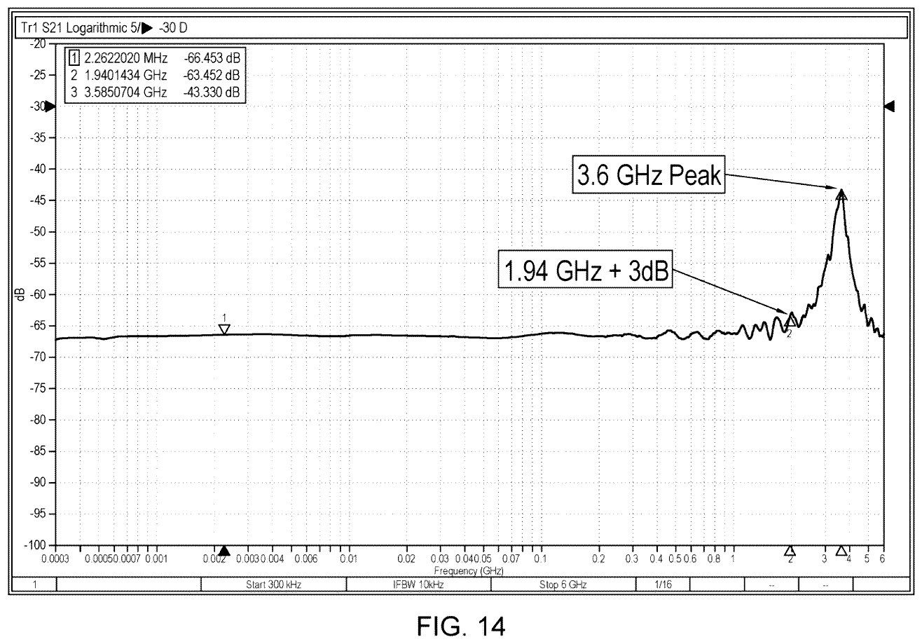

FIG. 14 shows a frequency response of a current probe according to the present disclosure.

### DETAILED DESCRIPTION OF THE EMBODIMENTS

Aspects of the invention will now be described by reference to example embodiments. It will be understood that the structures depicted and described herein are provided as illustrative examples, and are not intended to limit the scope of the present invention to only the depicted embodiments.

FIG. 1 shows a cross-sectional schematic of an example current probe 100 for use in a current measuring system. The current probe 100 comprises a resistive element such as a surface mounted device (SMD) shunt resistor 102 mounted on a top surface of dielectric layer 104. The current probe 100 may include a top conductive layer 106 and a bottom conductive layer 108 electrically connecting the resistor 102 to an input and output of the current probe respectively. The top and bottom conductive layers may be connected by a via 110. It will be understood that references to positional terms such as “top” and “bottom” are made with reference to the conceptual illustrations, and that while these terms are used for ease of reference they are not intended to be of a limiting nature. These terms are therefore to be understood as referring to an object when in a particular orientation such as that shown in the accompanying drawings.

The opposing current directions of current paths 106 and 108 result in mutual inductance cancellation between the current paths into 106 and out of 108 the current probe 100, and thereby facilitate a reduction in the total inductance of the current loop. The shunt resistor 102 may be placed face down such that the conductive layer of the resistor 102 is adjacent to the dielectric layer 104, as shown in current probe 100. By positioning the resistor 102 in this manner, the distance between the conductive layer of the resistor 102 and the current paths may be reduced, resulting in a greater mutual inductance cancellation between the resistor 102 and the current return path 108 to thereby further reduce the total loop inductance.

Dielectric layer 104 may be formed from e.g. a printed circuit board (PCB). However, for low inductance applications (such as high frequency switching) it is generally desirable the current paths to be separated by as small a spacing as possible, as a smaller separation between the conductive paths facilitates greater mutual inductance cancellation. As briefly discussed above, the advantages provided by the reduced inductance generally outweigh the disadvantages resulting from a higher capacitance of the current paths. Therefore, in implementations dielectric layer 104 may be an additional dielectric layer formed on a substrate layer. The substrate may be e.g. a PCB, and is not shown in FIG. 1. Preferably therefore, the thickness of the dielectric layer 104 is less than the thickness of the substrate (e.g. PCB) layer. For example, the dielectric layer 104 may have as small a thickness as possible within the given mechanical and/or manufacturing constraints of the current probe. This dielectric layer 104 further aids the reduction in the total loop inductance by facilitating an increase in the mutual inductance between the bottom current path 108 and the top current path 106/resistor 102. In alternative implementations, the dielectric layer may also form the substrate layer. For example, the dielectric layer may comprise a fibreglass layer within a PCB construction.

In e.g. current measurement systems, it is often seen as preferable to embed the current probe into a power loop in order to minimize the interconnect parasitics (such as a parasitic impedance) of the current probe. However, this means that the current measurement has to be included at the power module design stage, and the current probe may therefore not be compatible with the power module PCB layer stack-up and/or may be unsuitable for system layouts with a high component density.

Known non-embedded (e.g. insertable) current probes are typically less suitable for low inductance applications than embedded current shunts due to a higher system inductance resulting from e.g. the insertion inductance between the current probe and the rest of the measuring system. However, insertable current probes generally provide increased convenience and versatility in use due to the insertion connection system.

FIG. 2 shows a cross sectional schematic diagram of an insertable current probe 200. The low inductance provided by current probe 200 makes it particularly suitable for use as an insertable current probe, even for low inductance applications. However, it will be understood that current probe 200 may also be configured as an embedded current probe. Current probe 200 comprises current input and output regions 204 and 206 on opposite sides of the current probe, which may be connected to an external system using e.g. a solder connection as shown in FIG. 2. For example, as shown in FIG. 2, current input region 204 is provided on a “top” side of current probe 200, while current output region 206 is provided on the opposing “bottom” side of the probe 200. The direction of separation between the “top” and “bottom” surfaces of the stack of layers may be referred to herein as the stacking direction or dimension. It will be appreciated that current probe 200 is not limited to the use of a solder connection, and alternative connection methods, such as a bus bar connection, may be used. For example, current input and output regions 204, 206 may be configured for a bus bar connection using e.g. a spring contact, without requiring any other alterations to the design of current probe 200. By providing the current input and output regions 204 and 206 on opposing sides of the stack of layers 208 forming the current probe 200, the current probe 200 may be easily inserted into pre-existing systems.

Current probe 200 comprises a resistive element such as an SMD resistor 202 that may be arranged on a top surface of a dielectric material 208 in a similar manner to resistive element 102 of current probe 100. However, in contrast to current probe 100, current probe 200 comprises a stack 208 of multiple dielectric layers 208a-c. While three dielectric layers are shown in FIG. 2, it will be understood that current probe 200 may instead generally comprise a stack 208 of two or more layers, such as 2, 3, 4, 5, etc. layers, with each layer comprising a dielectric material. Each dielectric layer 208a-c may be formed from the same material or from different materials, and may also have the same or different thicknesses. For example, the dielectric layers 208a-c may each comprise and/or be formed from FR-4, or other materials suitable for radio/microwave frequencies. In implementations, middle dielectric layer 208b may comprise a substrate layer of current probe 200, such as a PCB. The middle dielectric layer 208b may therefore have a thickness greater than the outer dielectric layers and/or be formed from a different material to the outer dielectric layers.

Conductive layers 210a-d are provided on the top and bottom sides of each dielectric layer 208a-c. In current probe 200, the first conductive layer 210a on a top side of first dielectric layer 208a provides an input current path between the current input region 204 and the resistor 202. The second conductive layer 210b on a bottom side of the first dielectric layer 208a similarly provides an output current path between the resistor 202 and the current output region 206. The first and second conductive layers may be electrically connected by via 212, to form a current loop through the current probe 200.

To further enhance the mutual inductance cancellation between the current paths, the third and fourth conductive layers 201c, d may be connected to the first and second conductive layers respectively. The current probe 200 therefore comprises a set of input conductive layers 210a and c forming an input current path, and a set of output conductive layers 210b and d forming an output current path, such that the input and output conductive layers alternate or are interleaved in the stack of layers 208.

In FIG. 2, an example input current loop formed by the input conductive layers is shown in blue while an example output current loop formed by the output conductive layers is shown in red. The structure of current probe 200 therefore provides multiple current loops within the stack of layers 208. This structure may therefore be referred to as a “multi-loop structure”. The multi-loop structure facilitates further mutual inductance cancellation (and therefore reduces the total loop inductance) compared to the structure of current probe 100.

The interconnection region between the insertable current probe and an external system may also comprise a multi-loop structure, to facilitate a reduction in the insertion inductances of the current probe 200 via the same mechanisms described above.

Thus, current probe 200 may comprise input vias electrically connecting the set of input conductive layers and output vias electrically connecting the set of output conductive layers. While individual vias are depicted for the sake of clarity, it will be understood that each via shown in FIG. 2 may represent multiple vias. For example, in FIG. 2, the first (or “top”) conductive layer 210a is connected by first and second vias 214, 216 to the third conductive layer 210c to form the input current loop, while the second conductive layer 210b is connected by third and fourth vias 220, 218 to the fourth (or “bottom”) conductive layer 210d to form the output current loop, with the third via 220 forming part of via 212. It will be understood that this alternating connection pattern may be replicated with any additional conductive layers. For example, the first conductive layer 210a may be connected by vias to any “third”, “fifth”, etc. conductive layers, while the second conductive layer 210b may be connected to any “fourth”, “sixth”, etc. conductive layers. Thus, while current probe 200 is depicted with only a single input current loop and a single output current loop, it will be understood that the current probe may comprise multiple input and/or multiple output current loops by increasing the number of dielectric layers in the stack 208.

Generally speaking therefore, within current probe 200 via 214 connects the input paths in parallel to join to the external circuit (DUT), while via 218 connects the output paths in parallel to join to the external circuit (DUT). Via 216 directs the input current from the various paths to the sensing element (resistor), while via 212/220 connects the output from the sensing element to the parallel output paths. The interleaving of input and output paths creates multiple flux cancelling loops, also referred to as a multi-loop interconnect.

In addition to the further reduction in the inductance of the current probe, the provision of multiple dielectric layers 208a-c in the multi-loop structure results in an increased mechanical strength of the current probe 200, reducing the risk of mechanical stresses resulting in a breaking, fracturing or other failure of the current probe. This increased mechanical strength is particularly advantageous for insertable current probes, such as that shown in FIG. 2, due to the need for the current probe to be handled e.g. during insertion into a system. For example, while the current probe 100 may typically require a layer thickness of between about 200 μm and about 1000 μm to provide a suitable mechanical strength, the individual layers 208a-c of the current probe 200 may each have a thickness of less than about 200 μm, for example about 50 μm, or even less. However, one or some of the layers, for example a substrate layer such as middle dielectric layer 208b, may be provided with an increased thickness, for example between about 200 μm and about 1000 μm, in order to further increase the mechanical strength of the current probe 200 while retaining the benefits provided by thinner outer dielectric layers 208a, c. As such, it will be understood that some layers of stack may not include corresponding conductive layers, and may instead be provided to e.g. further enhance the mechanical strength of the current probe. One such example current probe is depicted in FIG. 11, comprising only a single input current path and a single output current path separated by a first dielectric layer. In this implementation, mutual inductance cancellation is provided only at the top layers of the probe.

The input conductive layers forming the input current path may all be connected by two vias, and/or additional vias may be provided connecting a portion of the input conductive layers. For example, in implementations comprising three input conductive layers (e.g. “first”, “third” and “fifth” conductive layers), a first and second via may be provided connecting all three input conductive layers. Alternatively, the first and second conductive vias may connect only the “first” and “third” conductive layers, while third and fourth vias may be provided to connect the “fifth” conductive layer with the “first” or “third” conductive layers. Any other arrangement of vias suitably connecting the input conductive layers may also be provided. It will be appreciated that the above discussion applies equally to the output conductive layers (e.g. the “second”, “fourth”, etc. conductive layers) forming the output current path.

It will be understood that embedded current probes may also benefit from improved mechanical strength and greater mutual inductance cancellation, particularly in relation to low inductance applications. As such, embedded current probes comprising the multi-loop structure of current probe 200 are contemplated within the scope of the present disclosure.

It will be further understood that while current probes 100, 200 have been shown with a single resistor 102, 202 for simplicity, current probes 100, 200 may each comprise one or more resistors. The use of multiple separate resistors in current probes 100, 200 may reduce the skin effect compared to a single, lower impedance resistor at higher switching frequencies. The resistors may be arranged into any suitable pattern, for example a semicircular shape as shown in FIGS. 3a and b, which show top and side views of an example insertable current probe 300. Current probe 300 includes multiple resistive elements such as SMD resistors 302 and an optional coaxial connector 304 for connecting the resistors 302 to a single input/output. The structure of current probe 300 is otherwise identical to that described above with regards to current probe 200, including input and output current regions 306, 308. FIGS. 3c and d show bottom and top views respectively of an alternative current probe 300a. Current probe 300a is structurally similar to current probe 300, but comprises resistive elements 302 on an output surface (i.e. the surface comprising output current region 308) of the stack of layers, while a measurement loop structure 310 is provided on the input surface (i.e. the surface comprising input current region 306). It will be understood that the current probe 300 may also comprise a current measurement loop structure, for example on its output surface (not shown).

The use of a semi-circular arrangement for the resistors 302 results in a spacing and angle between adjacent resistors 302 that may assist in reducing or avoiding the proximity effect, thereby assisting in the maintenance of a desired impedance level for the current probe at high switching frequencies. However, other arrangements of resistors may also be used, such as a straight or “flat” arrangement 1302 as shown for current probe 1300 of FIG. 13.

An enhanced view of current probe 300a is depicted in FIG. 12, showing coaxial output connector 1202, filter resistors (R_{comp}) 1204a-d, and filter inductors (L_{comp}) 1206a,b.

FIG. 7 shows a frequency response of an example current probe according to the present disclosure for MHz frequencies. As can be seen via e.g. a comparison to FIG. 9, the bandwidth of the “flat” ±3 dB portion of the frequency response is significantly increased in comparison to existing designs. In addition, the peak of the current probe resonance is also at a much higher frequency than known current probes due to the much lower parasitic inductance, reducing the likelihood of the resonance falling within any frequencies of interest. Current probes according to the present disclosure therefore provide a much greater bandwidth for performing measurements on currents, and especially on currents with shorter (e.g. nanosecond) switching times. FIG. 14 shows a further frequency response of an example current probe according to the present disclosure for GHz frequencies.

FIG. 4 depicts a schematic diagram of a current measuring system 400. The system 400 comprises a power electronics stage 1, a compensation filter stage 2, a first differential amplifier stage 3, a second differential amplifier stage 4 and an output stage 5 for providing an output to a current measuring device, such as an oscilloscope. The second differential amplifier stage 4 may also be referred to as an input stage. It will be appreciated that the first and second amplifier stages 3 and 4 are optional, and each may be omitted from system 100 or otherwise be combined into a single amplifier stage. Additionally, power electronics stage 1 may optionally (for example when utilising an insertable current probe) comprise a multi-layer interconnect structure 406 in the interconnection region of the current probe and external system. This multi-layer interconnect structure 406 may be configured in a similar manner to the multi-layer or multi-loop structure shown in current probe 200. This structure 406 may facilitate mutual inductance cancellation of the insertion inductances of an insertable probe, and further reduce a total system inductance.

The power electronics stage 1 comprises one or more shunt resistors 402, for example resistors 102, 202, 302 of current probes 100, 200, 300. As such, the power electronics stage 1 of the system may comprise one or more current probes. Current probes such as current probes 100, 200, 300 may therefore comprise a current measurement loop. FIG. 5a shows an example current measurement loop 500 provided on a bottom surface (i.e. a surface comprising current output region 308) of the current probe 300. It will be understood that the structure and placement of current loop 500 is merely illustrative, and is not intended to be of a limiting nature.

FIG. 5b shows an equivalent model circuit 502 of the current probe 300 with a measurement loop, in which Lₛₕᵤₙₜ is the inductance of the probe circuit between the current measurement points, Lₘ is the mutual inductance between the power and measurement loops, Rₛₕᵤₙₜ is the resistance of the measurement circuit between the measurement points, and L_{conn} is an extra inductance introduced into the external power-loop due to its interconnect with the current probe. If the current probe is integrated directly into the power-loop, then L_{conn} may be zero. Rₛₕᵤₙₜ is dominated by the shunt resistance, while Lₘ may be minimized in the probe design by keeping the power and measurement loops perpendicular, as shown in FIG. 5a. C_{parasitic} is the equivalent parasitic capacitance that appears across the shunt resistor, bypassing it. C_{parasitic} is composed of components from both the probe circuit and the system under test.

From the circuit 502, it will be understood that the natural frequency wo of the current probe is:

$${ω}_{0} = \frac{1}{\sqrt{{L}_{shunt} {C}_{parasitic}}} \qquad 1$$

and that the damping ratio ζ of the current probe is:

$$ζ = \frac{R}{2} \sqrt{\frac{{C}_{parasitic}}{{L}_{shunt}}} \qquad 2$$

Thus, by reducing or minimising the shunt inductance Lₛₕᵤₙₜ not only can the device be protected from voltage spikes, but the damping ratio of the current probe will also be increased, and its natural frequency increased away from frequencies of interest.

It will be further understood from circuit 502 that any resistive type shunt introduces an inductive or parasitic zero into voltage measurements. In particular, the inductive zero of circuit 502 results in the measured output signal having a derivative component of:

$$\frac{{L}_{shunt} + {L}_{m}}{{R}_{shunt}} \qquad 3$$

Under a high speed switching edge this derivative output can be very large, reducing the accuracy of the measured signal.

System 400 may therefore include a compensation filter stage 2 for removing this inductive zero. The compensation filter stage 2 may comprise a low pass filter 404, such as a differential low pass filter. The voltage across the current probe may be passed through the filter, to reduce the dependency of the system bandwidth on the shunt resistance. Without the low pass filter, lower shunt resistances generally provide a lower bandwidth, leading to a large resistance being required for high bandwidth devices. The large resistances may result in power dissipation issues, particularly when performing continuous measurements on high current signals. Furthermore, the high required resistances result in many high bandwidth oscilloscopes having a significant range limitation. Thus, high accuracy high bandwidth attenuators would be required to perform measurements of larger currents. While this high resistance attenuates the inductive zero (as can be seen from expression 3 above), the inductive zero is still present in the frequency response, and causes derivative distortion of the output signal.

An example compensation filter 600 for system 400 is shown in FIG. 6. The filter 600 may be configured to receive an output from the power circuit stage 1, and provide an output to the first amplifier stage 3. The filter is preferably configured such that Rₛₕᵤₙₜ>>R₃>>R₁, to ensure that the filter does not conduct significant power loop current and also does not disrupt the operation of later differential amplifiers, such as differential amplifier stages 3 and 4. In examples, the compensation filter 600 may comprise an amplifier to convert the signal to a balanced differential signal.

The example filter 600 may be formed from an inductive filter utilizing high bandwidth SMD chip-type inductors and the input impedance of an amplifier stage. Advantageously, the filter 600 provides two degrees of freedom for altering the pole positions of the filter. The resistance R₃ and the inductance L_{comp} can each be adjusted in order to finely tune the filter frequency response.

Some high bandwidth differential amplifiers, such as those suitable for amplification stages 3 and 4 of the system 400, require specific feedback resistances in order to achieve their maximum bandwidth. Due to this, a capacitive feedback low pass filter is less suitable, as only the capacitor size would be variable. Hence, the use of an inductive filter (i.e. a filter stage 2 comprising L_{comp}) is advantageous in some example implementations of the system 400.

It is generally beneficial to tune the compensation filter stage 2 as accurately as possible. For example, FIG. 8 shows simulated effects of compensation error. In particular, FIG. 8(a) shows the frequency responses of example under and over compensated ultra-fast current probes, while FIG. 8(b) shows the corresponding switching current measurements of those example. As shown in the example implementation of FIG. 8, a 1.5 dB over compensation results in a false tail current with a magnitude of 4.5 A. It will be understood that different implementations and/or test conditions (such as a different switching speed or current) may result in a different false tail current magnitude.

To avoid distortions of the frequency response of filter 600, the parasitic inductive reactance of R₃ preferably should be significantly less than its resistance. To facilitate this, R₃ may be formed from multiple separate resistors. For example, R₃ may be formed from three separate resistive elements. It will be understood that other numbers and/or resistor types may be used to construct R₃.

By providing an output of the filter 600 to a differential amplifier stage 3, the unbalanced differential signal at the output of the inductor may be converted into a balanced differential signal allowing the later removal of common mode noise. Beneficially, as long as Lₛₕᵤₙₜ and C_{parasitic} are kept sufficiently small that resonant effects to not occur within the frequencies of interest, the current probe frequency response will be dominated by the response of the differential amplifiers.

The compensation filter stage 2 may be an active filter comprising an amplifier. However, current measuring systems comprising a passive filter stage 2 may also be implemented within the scope of the present disclosure. Such passive system implementations may comprise neither of the amplifier stages 3 and 4, or any amplifiers within the filter stage 2. One such example system 1000a is depicted in FIG. 10A.

FIG. 10A depicts a schematic diagram of a passive current measuring system 1000a. The system 1000a comprises a power electronics stage 1 and a compensation filter stage 2 that provides an output directly to the output stage for use by a current measuring device, such as an oscilloscope. As discussed above, in contrast to the active system 400, passive system 1000a does not comprise either of the first and second amplifier stages 3 and 4.

As shown in system 1000b of FIG. 10b, the power electronics stage 1 may optionally (for example when utilising an insertable current probe) comprise a multi-layer interconnect structure 1006 in the interconnection region of the current probe and external system. As in system 400, this multi-layer interconnect structure may be configured in a similar manner to the multi-layer or multi-loop structure shown in current probe 200. This structure may to facilitate mutual inductance cancellation of the insertion inductances of an insertable probe, and further reduce a total system inductance. Is some designs, a common mode choke may be added to the passive system to facilitate common mode noise rejection.

FIG. 10C depicts an example circuit diagram of an implementation of the power electronics stage 1 and filter stage 2 of passive measurement systems 1000a, b. The power electronics stage 1 comprises one or more shunt resistors 1002, for example resistors 102, 202, 302 of current probes 100, 200, 300. As such, the power electronics stage 1 of the system may comprise one or more current probes. Current probes such as current probes 100, 200, 300 may therefore comprise a current measurement loop.

The filter stage 2 comprises a plurality of inductors L1, L2 arranged in series and resistors R₁, R₂, R₃, and R₄ arranged in parallel to form a low pass filter 1004. The filter stage 2 of systems 1000a, b may differ from that of system 400 due to the lack of buffering from the “active” operational amplifier stages 3 and 4. As a result, the loading by e.g. the measuring oscilloscope may need to be considered and/or accounted for in the design and components of some implementations of the passive filter stage 2 of systems 1000a, b.

It will be understood that structure shown in FIG. 10C is merely illustrative, and is not intended to limit the scope of the present disclosure.

Returning now to FIG. 4, the balanced differential signal output from the first amplifier stage 3 may be passed over a split between analogue and digital grounds. As shown in FIG. 4, the analogue and digital grounds may be separated by e.g. a 10Ω resistance. Additionally or alternatively, the analogue and digital grounds may be separated by other passive components, such as an inductor, and/or may be disconnected completely.

This split in the ground plane may beneficially discourage any power ground currents from flowing into the sensitive measurement circuitry and equipment. The power ground currents have the potential to be quite large and contain significant high frequency content. These currents may therefore significantly corrupt measurement signals.

Additionally, to remove the need for isolated power supplies a star grounding technique may be adopted. Optionally, the star grounding techniques may employ common mode chokes, for example placed between different ground references.

The differential signal may be further amplified in the second differential amplifier stage 4, before being converted into a signal suitable for use by an oscilloscope or other suitable equipment. For example, the differential signal may be converted into a single ended signal using a differential amplifier by utilizing just one output leg, with the other leg loaded by an equivalent 50Ω impedance so that the two differential lines remain symmetrical. This may increase or maximize the common mode rejection ratio (CMRR) of the amplifier. It will be understood that the use of a 50Ω impedance is merely provided as an example, and that any suitable impedance may be chosen based on the input requirements of the equipment (e.g. oscilloscope).

The addition of the amplification stages 3 and 4 has a further advantage of buffering the current probe from the oscilloscope input, with the resistors in the amplifier feedback loops blocking any direct connection. This protects the oscilloscope input from any failures of the current probe. For example, an open circuit failure of the current probe may result in high voltages to be present across the current probe resistor.

Those skilled in the art will understand that in the preceding description and appended claims, positional terms such as ‘top’, ‘bottom’, ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in any embodiments, whether alone or in any appropriate combination with any other feature disclosed or illustrated herein.

1. A radio/microwave frequency current probe comprising:
one or more resistive elements electrically connected between a current input region and a current output region; and
a stack of layers, wherein each layer comprises a dielectric material;
wherein for each of the one or more resistive elements, the current probe comprises:
a plurality of conductive paths each separated by one or more of the layers, wherein a first set of one or more conductive paths are configured to provide a current path between the current input region and the resistive element, and a second set of one or more conductive paths are configured to provide a current path between the resistive element and the current output region; and
the plurality of conductive paths arranged such that the first and second sets of conductive paths alternate in the stack of layers.

2. The current probe of claim 1, wherein the conductive paths of the first set of conductive paths are electrically connected via one or more vias.

3. The current probe of claim 1, wherein the conductive paths of the second set of conductive paths are electrically connected via one or more vias.

4. The current probe of claim 1, wherein one or more layers of the stack of layers each have a thickness in the stacking direction of between about 50 μm and about 200 μm.

5. The current probe of claim 1, wherein each layer of the stack of layers comprises the same dielectric material.

6. The current probe of claim 1, wherein at least two layers of the stack of layers comprise different dielectric materials.

7. The current probe of claim 1, wherein the current probe comprises a plurality of resistive elements, and optionally wherein the plurality of resistive elements are arranged in a semi-circular arrangement.

8. The current probe of claim 1, wherein the one or more resistive elements are mounted to a surface of the stack of layers.

9. The current probe of claim 8, wherein the one or more resistive elements are arranged such that a conductive surface of the one or more resistive elements are adjacent to the stack of layers.

10. The current probe of claim 1, wherein the current input region and the current output region are provided on opposing sides of the stack of layers.

11. The current probe of claim 10, wherein the current input region and the current output region are configured to be soldered or clamped to an external power loop or bus bar.

12. The current probe of claim 1, wherein the stack of layers comprises at least three layers, the second layer being arranged between the first and third layers;
wherein the first set of conductive paths comprises a first conductive path on an outer surface of the first layer and a third conductive path between the second and third layers; and
the second set of conductive paths comprises a second conductive path between the first and second layers and a fourth conductive path on an outer surface of the third conductive layer.

13. The current probe of claim 1, wherein the layers of the stack of layers are layers of a multilayer printed circuit board.

14. A system for measuring currents, comprising a one or more current probes according to claim 1.

15. The system of claim 14, further comprising a compensation filter arranged to receive an output signal from the one or more current probes, the compensation filter configured to reduce an inductive zero from the output of the one or more current probes.

16. The system of claim 15, wherein the compensation filter comprises a low pass filter.

17. The system of claim 15, wherein the compensation filter comprises one or more further resistive elements electrically connected to an input for a reference voltage.

18. The system of claim 17, wherein the one or more further resistive elements comprise a plurality of resistive elements.

19. The system of claim 15, wherein the compensation filter comprises an inductive low pass filter.

20. The system of claim 14, further comprising a first differential amplifier configured to receive output signals from the compensation filter.

21. The system of claim 20, further comprising second differential amplifier configured to receive output signals from the first differential amplifier, and provide an output for use by an external system.

22. The system of claim 21, wherein the second differential amplifier comprises an output load connected to a first output leg, and wherein the second output leg is configured to provide a single ended signal for use by the external system

23. The system of claim 14, wherein the system is formed on a printed circuit board.

24. A method for reducing the inductance of the current probe of claim 1, the method comprising:
providing a first set of one or more conductive paths and a second set of one or more conductive paths in a stack of layers, wherein each layer comprises a dielectric material;
arranging the first and second set of conductive paths such that they alternate within the stack of layers; and
providing an input current through the first set of conductive paths and an output current though the second set of conductive paths, such that an inductance of the current probe is reduced by mutual inductance cancelation between the first and second set of conductive paths.

25. A method of using the current probe of claim 1 to measure currents with microwave/radio frequencies, the method comprising:
providing an input current to the current probe;
reducing the inductance of the current probe by
arranging a first set and a second set of conductive paths in a stack of layers comprised of a dielectric material, such that the first set and the second set of conductive paths alternate within the stack of layers; and
providing an output current though the second set of conductive paths, such that an inductance of the current probe is reduced by mutual inductance cancelation between the first set and the second set of conductive paths;
receiving an output signal from the current probe, wherein the output signal is representative of a current through the current probe; and
providing the output signal to a measurement system.
